(19) United States
(12) Patent Application Publication
(10) Pub. No.: US 2006/0071721 A1
(43) Pub. Date: Apr. 6, 2006

(54) REDUCING SIZE OF CAPACITORS IN FILTERS

(75) Inventors: Prakash EASWARAN, Bangalore (IN); Koushik KRISHNAN, Bangalore (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 10/711,741

(22) Filed: Oct. 1, 2004

(51) Int. Cl. H03L 7/00

(52) U.S. Cl. 331/17

(57) ABSTRACT

An active filter circuit containing small capacitors. Due to the presence of such small capacitors, components such as PLL can potentially be integrated into integrated circuits. In an embodiment, the filter circuit is implemented by having a combination of a first capacitor and a first resistor connected in series providing the input signal to the input terminal of a operational amplifier, and a second resistor being connected in parallel to the combination. A second capacitor may be connected between the input and output terminals of the operational amplifier. The first capacitor may be chosen to be small by choosing the second resistor to be of a large resistance. Any noise introduced by such a large resistor may be attenuated by choosing the first resistor to be small.

### BACKGROUND OF THE INVENTION

1. Field of the Invention

The present invention relates to the design of circuits used in communication systems, and more specifically to reducing the size of capacitors used in filters.

2. Related Art

Filters are used in various components. An example of such a component is a phase lock loop (PLL). As is well known, a PLL is generally used to generate an output signal, which is synchronized with an input signal. Often, the output signal is generated to have a frequency equaling a desired multiple (“frequency multiple”) times the frequency of the input signal. PLLs find applications in severed areas of communication (including long haul, short distance, wire-based an wireless), as is well known in the relevant arts.

In one prior embodiment, a PLL contains a phase detector (used synonymous with phase-frequency detector, for multiple) which compares the phase of a divided (by the frequency multiple) output signal and the input signal (as a reference signal) in each comparison cycle. The phase of the output signal is adjusted according to the comparison such that the divided output signal is received in phase with the input signal.

A filter is often used to control such adjustments over multiple comparison cycles. The output of the filter indicates the extent to which the phase of the output signal is to be adjusted such that the output signal is generated with a desired phase/frequency. Thus, a filter may receive a signal indicating the phase error detected in a phase detector and generate another signal to adjust the phase of the output signal.

It may be desirable to provide filters with low bandwidth, generally for noise immunity (e.g., not to be affected by short term fluctuations due to reasons such as jitter and other types of noise) of the PLL loop. In one embodiment, the bandwidth of filter needs to be not more than 1/10 of the frequency of the input signal.

In one prior approach in which filters are implemented using a tors, the value of the capacitors controls the bandwidth of the filter. The filter bandwidth can be designed to be low by choosing large a tors. However, large capacitors are often difficult to fabricate as a part of integrated circuits. Such large capacitors may be provided as external components, but the corresponding implementations add to overall cost, require additional space/area, and also would be susceptible to more noise.

Accordingly, it is generally desired that the size of such capacitors be minimized in PLL implementations.

### BRIEF DESCRIPTION OF THE DRAWINGS

The present invention will be described with reference to the following accompanying drawings.

FIG. 1 is a block diagram of an example phase lock loop (PLL) in which severed aspects of the present invention are implemented.

FIG. 2 is a circuit diagram illustrating the details of a filter circuit in one prior embodiment.

FIG. 3 is a circuit diagram illustrating the details of a filter circuit according to an aspect of the present invention.

FIG. 4 is a bock diagram illustrating an example device in which various aspects of the present invention can be implemented.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

1. Overview

An aspect of the present invention enables a filter circuit of low bandwidth to be obtained by using capacitors of small sizes. In one embodiment, a passive component is connected between the input terminal and the output terminal of an operational amplifier. The input terminal is further connected to a combination of a first capacitor and a first resistor connected is series, with a second resistor being connected in parallel to the combination. In the case of a first order filter circuit, the passive component contains a resistor, and in the case of a second order filter circuit, the passive component contains a capacitor.

Low bandwidth may be obtained for the filter by selecting appropriate values for resistors capacitors. A small value of the capacitor can be made to be acceptable (i.e., to obtain desired transfer function) by increasing the resistance value of the second resistor. The noise due to the large resistor is attenuated by selecting a small value resistor for the first resistor.

As a result, low bandwidth filter circuits of acceptable noise can be realized using only small capacitors. The filter circuits thus designed can be incorporated into severed components such as PLLs. Due to the use of small capacitors, such components can be fabricated as a part of an integrated circuit, thereby leading to advantages such as reduced cost/area requirement, and more noise immunity.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well-known structures or operations are not shown in detail to avoid obscuring the invention.

2. PLL

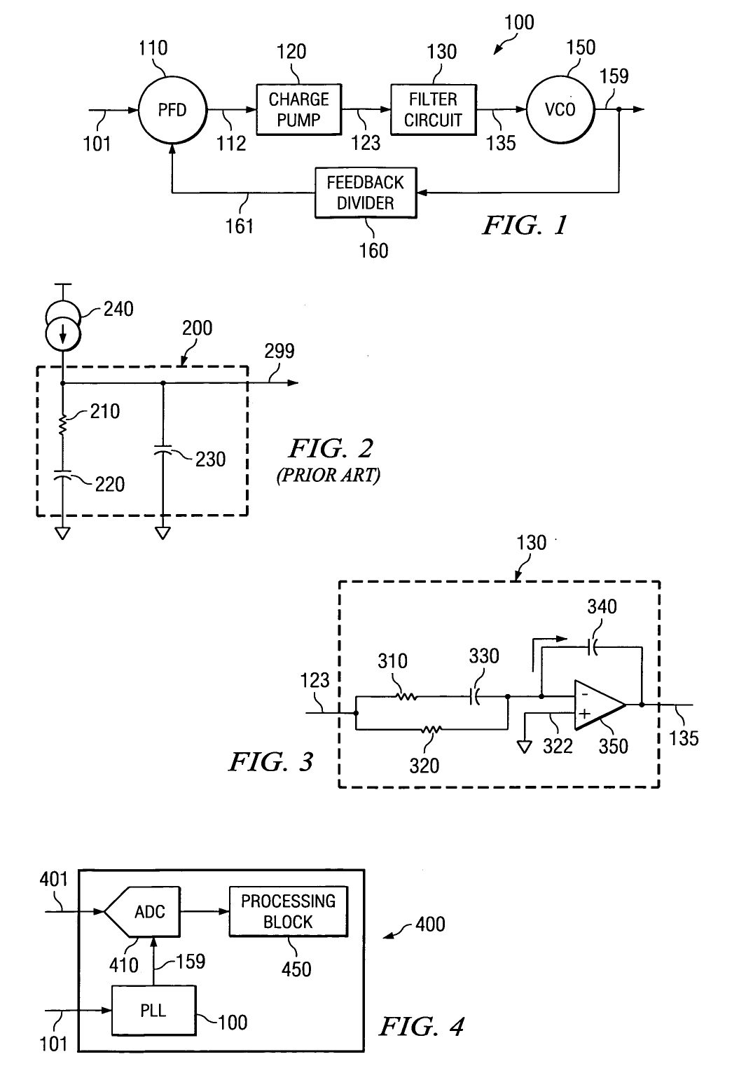

FIG. 1 is a block diagram of an example phase lock loop (PLL) in which various aspects of the present invention can be implemented. PLL 100 is shown containing phase frequency detector (PFD) 110, charge pump 120, filter circuit 130, voltage controlled oscillator (VCO) 150, and frequency divider 160. Each block is described below.

PFD 110 compares the phases of reference signal received on path 101 and feedback signal received on path 161, and generates an error signal on path 112 representing the difference in the phases of signals 101 and 161. Error signal 112 represents the phase error in the form of time signals, i.e., the path is asserted for a time duration proportionate to the phase error.

Charge pump 120 receives error signal 112 and converts the corresponding time signals into electric signals. The electric signals are provided on path 123. In one embodiment described below, the electrical signals are provided in the form of voltage signals. PFD 110 and charge pump 120 are implemented in a known way.

Filter circuit 130 indicates on path 135 the extent (correction value, or signal) to which the phase of the output signal 159 should be adjusted by VCO 150. The correction value is determined by the transfer function of filter circuit 130, as well as magnitude of error signal 112. As noted above, filter circuit 130 may need to be implemented with a low bandwidth and without using large capacitors. The manner in which filter circuit 130 may be implemented cording to various aspects of the present invention is described in sections below.

VCO 150 adjusts the frequency of output signal (having N-times the frequency of reference signal 101) provided on path 159 bused on the correction value received on path 135. Since VCO 150 is controlled by voltage inputs, correction value 135 is received in the form of electric voltage. Feedback divider 160 divides the frequency of output signal 159 by N-times and provides the feedback signal on path 161.

Thus, the loop of VCO 15, feedback divider 160, PFD 110, charge pump 120, and filter circuit 130 adjusts the frequency/phase of output signal 159 until the phase error is substantially zero, in which case the steady state is said to have been reached.

As noted above, for loop stability the bandwidth of filter circuit (for low reference frequency & low jitter as mentioned earlier) 130 needs to be low. Various aspects of the present invention enable filter circuit 130 to be implemented with small capacitors. The advantages of the present invention may be appreciated in comparison to a prior circuit which does not employ one or more features of the present invention. Accordingly, the details of such a prior embodiment are described first below with reference to FIG. 2.

3. Prior Filter Circuit

FIG. 2 is a circuit diagram illustrating the details of filter circuit 200 in one prior embodiment. Filter circuit 200 is shown containing resistor 210, and capacitors 220 and 230. Filter circuit 200 is shown receiving electric signal in the form of electric current, which is represented by current source 240. Each component is described below.

Resistor 210 and capacitor 220 together operate as a low pass filter to remove the noise components in the raved electric signal. Capacitor 230 removes switching noise in the filtered signal and provides the filtered signal on path 299.

It may be noted that a pole and a zero are required to be present in the gain function of filter circuit for stability of a PLL. The pole is achieved with the operation of resistor 210 and capacitor 230, and the zero is achieved by the combination of resistor 210, and capacitors 220 and 230. Assuming that the resistance of resistor 210 equals R₂, and the capacitances of capacitors 230 and 220 respectively equal C₁ and C₂, the gain function (which is the impedance) of filter circuit 200, which contains both pole and zero is given by equation (1) below.
G=((1+T₂s)*C0)/((1+T₁s)*s) Equation (1)

wherein s represents Laplace constant, T₂=R₂C₂,

*, + and/represent multiplication, addition and division operations,

T1=R₂(C₁*C₂)/(C₁+C₂) and

C0=I in/(2*pi)(C₁+C₂), wherein I in is the amount of current in the electric signal and pi is a constant equaling 22/7.

For a desired bandwidth (Wp) and a desired phase margin (phi) of a PLL, it can be shown that the maximal in the phase curve is obtained for the corresponding values of T₁ and Wp as given below with equations (2) and (3).
T₁=(sec(phi)−tan(phi))/Wp Equation (2)
Wp=1/sqrt(T₁*T₂) Equation (3)

wherein sec and tan are the trigonometric secant and tangent functions, and sqrt is square root.

Assuming that the gain of phase frequency detector and charge pump together is Kphi, and the gain of VCO is Kv, then the component values of filter circuit 200 are given below.
C₁=((T₁KphiKv)/(T₂Wp²N))sqrt((1+(Wp*T₁)²)/(1+(Wp*T₂)²)) Equation (4)
C₂=C₁((T2/T1)−1) Equation (5)
R₂=T₂/C₂ Equation (6)

4. Problem(s) with Prior Filter Circuit

As noted above, the bandwidth of filter circuit 130 generally needs to be low. One problem with such a requirement in prior filter circuit described above, is that C₂ needs to be large for low bandwidth and better phase margin as may be observed from equations (2), (3) and (5) of above.

In one prior embodiment, such large capacitors are placed outside of integrated circuits, and is undesirable for reasons noted in the background section. Alternatively, the value of capacitor 220 can be decreased by increasing the value of resistor 210. An increase in R₂ causes a corresponding increase in noise.

A filter circuit according to various aspects of the present invention solves one or more of the problems as described below with reference to FIG. 3.

5. Filter Circuit

FIG. 3 is a circuit diagram illustrating the details of a filter circuit according to an aspect of the present invention. For illustration, the details of the filter circuit is described with reference to FIG. 1. However, the filter circuit can be implemented in other implementations as well. Filter circuit 130 is shown containing resistors 310 and 320, capacitors 330 and 340, and operational amplifier 350. Each component is described below.

Resistors 310, 320 and capacitor 330 together remove the noise components in the received electrical signal on path 123 and provide the filtered signal on inverting input terminal of operational amplifier 350.

Capacitor 340 operates to provide the desired gain of filter circuit 130, in addition to providing the pole at origin. Operational amplifier 350 amplifies the filtered signal and provides the amplified filtered signal on path 135 for further processing.

Assuming that the resistance of resistors 310 and 320 respectively equal R_{A} and R_{B}, and the capacitances of capacitors 330 and 340 respectively equal C_{A} and C_{B}, the gain function (G) of filter circuit 130, which contains both pole and zero is given by equation (7) (assuming that operational amplifier 350 is ideal) below:
G=((1+T₂s)*C0)/((1+T₁s)*s) Equation (7)

wherein s is Laplace constant, T₂=(R_{A}+R_{B}) C_{A}, T1=R_{A} C_{A}, C0=Vin/(2*pi)(R_{B} C_{B}), Vin is the amount of voltage in the electric signal, and pi is a constant equaling 22/7.

For a desired bandwidth (Wp) and a desired phase margin (phi) of a PLL, the component values of filter circuit 130 are given by the equations below.
R_{B}=((KphiKv)/(C_{B}Wp²N))sqrt((1+(Wp*T₂)²)/(1+(Wp*T₁)²)) Equation (8)
wherein sqrt represents the square root operation.
   R_{A}=R_{B}/((T2/T1)−1) Equation (9)
   C_{A}=T₁/R_{A} Equation (10)

It may be observed from the above equations that R_{A} nd R_{B} depend on bandwidth Wp (and/or T2/T1), the value of C_{B} may be selected to set the value R_{B}, and C_{A} is independent of Wp.

From Equation (8) above, it may be appreciated that R_{B} needs to be high for a low bandwidth Wp. In general, large resistors are sources of noise. However, the noise due to high value of R_{B} would get attenuated due to the parallel connection of R_{A}. Thus, the noise at the output is (substantially) due to R_{A} only and the noise due to R_{B} is attenuated.

Therefore, with a high resistance value of resistor 320, the value of capacitor is reduced without increasing noise. Such a resistor with a high resistance can be easily integrated into integrated circuits (compared to large capacitors).

In one embodiment, assuming that a PLL is to be designed for Kv=240e6 Hz/V, Kphi=100e−6 A, N=480/13, Wp=100e3*2* pi rad/s, and Phi=60* pi/180 rad, then the values of prior filter circuit 200 and filter circuit 130 are given below.

R1=1 Kohms, C1=450 pF, and C2=5.2 nF for prior filter circuit 200. However, RA=31 Kohms, RB=410 Kohms, CA=13 pF, and CB=150 pF for filter circuit 130.

It may be noted that the C2 (of prior filter circuit 200) is a large value compared to C_{B} (of filter circuit 130). However, resistance value of R_{B} is high, and the noise caused by which is attenuated, as noted above.

It may be noted that structure of FIG. 3 implements a second order filter. However, a first order filter circuit may be implemented by replacing capacitor 340 (passive component) with a resistor.

In addition, non-inverting terminal of operational amplifier is shown connected to ground and inverting terminal is shown connected to reeve signal 123 through components 310, 320, and 330. However, non-inverting terminal of operational amplifier 350 can be connected to reeve electric signal 123 and inverting terminal can be connected to ground through components 310, 320, and 330.

Furthermore, given that the non-inverting input terminal of FIG. 3 is connected to ground, the approach of FIG. 3 can be easily extended to differential implementations. In addition, filter circuit and PLL can be implemented in various devices. An example device is described below in further detail.

6. Device

FIG. 4 is a block diagram illustrating an example device in which various aspects of the present invention can be implemented. For conciseness, only the portions of device 400, as relevant to some aspects of the present invention are included. However, various aspects of the present invention can be implemented in other devices as well. Device 400 is shown containing PLL 100, analog to digital converter (ADC) 410 and processing block 450. Each block is described below in further detail.

PLL 100 receives generates a dock signal on path 159 based on an input signal received on path 101. ADC 410 samples an analog signal received on path 401 to generate digital values. Processing block 450 contains one or more processing units to process the digital values.

### 7. CONCLUSION

While various embodiments of the present invention have been described above, it should be understood that they have been presented by way of example only, and not limitation. Thus, the breadth and scope of the present invention should not be limited by any of the above described exemplary embodiments, but should be defined only in ac dance with the following claims and their equivalents.

What is claimed is:

1. A filter circuit processing an input signal, said filter circuit comprising:
an operational amplifier containing an input terminal and an output terminal, said input signal being received on said input terminal;
a passive element coupled between said input terminal and said output terminal;
a first capacitor and a first resistor connected in series, and providing said input signal to said input terminal; and
a second resistor connected in parallel to said first capacitor and said first resistor connected in series.

2. The filter circuit of claim 1, wherein said second resistor ha, more resistance than said first resistor.

3. The filter circuit of claim 2, wherein said passive element comprises a resistor.

4. The filter circuit of claim 2, wherein said passive element comprises a capacitor.

5. A phase locked loop (PLL) generating an output signal synchronized with a reference signal, said PLL comprising:
a phase frequency divider (PFD) comparing the phase of said output signal with the phase of said reference signal and generating an error signal representing the difference of phases of said output signal and said reference signal;
an active filter circuit generating a correction signal based on a magnitude of said error signal, said active filter circuit comprising:
an operational amplifier containing an input terminal and an output terminal;
a passive element coupled between said input terminal and said output terminal;
a first capacitor and a first resistor connected in series, and providing said error signal as an input signal to said input terminal; and
a second resistor connected in parallel to said first capacitor and said first resistor connected in series; and
an oscillator adjusting the phase of said output signal cording to said correction signal.

6. The PLL of claim 5, wherein said second resistor has more resistance than said first resistor.

7. The PLL of claim 6, wherein said passive element comprises a resistor.

8. The PLL of claim 6, wherein said passive element comprises a capacitor.

9. The PLL of claim 8, further comprises:
a charge pump converting said error signal into said input signal; and
a feedback divider dividing said output signal to generate a signal for comparison by said PFD,
wherein said oscillator comprises a voltage controlled oscillator.

10. A device comprising:
a filter circuit processing an input signal, said filter circuit comprising:
an operational amplifier containing an input terminal and an output terminal, said input signal being received on said input terminal;
a passive element coupled between said input terminal and said output terminal;
a first capacitor and a first resistor connected in series, and providing said input signal to said input terminal; and
a second resistor connected in parallel to said first capacitor and said first resistor connected in series.

11. The device of claim 10, further comprising a processing unit processing a plurality of digital values generated using an output signal received on said output terminal.

12. The device of claim 11, further comprising:
a phase locked loop (PLL), said PLL comprising said filter, and an oscillator being controlled by said output signal, said PLL generating a clock signal; and
an ADC sampling an analog signal at time points specified by said clock signal to generate said plurality of digital values.

13. The device of claim 11, wherein said second resistor has more resistance than said first resistor.

14. The device of claim 13, wherein said passive element comprises a resistor.

15. The device of claim 13, wherein said passive element comprises a capacitor.
